(19) United States
(12) Patent Application Publication
(10) Pub. No.: US 2025/0377563 A1
(43) Pub. Date: Dec. 11, 2025

(54) CIRCULARLY POLARIZED LIGHT EMITTING DISPLAY DEVICE

(71) Applicant: POSTECH RESEARCH AND BUSINESS DEVELOPMENT FOUNDATION, Pohang-si (KR)

(72) Inventor: Su Seok CHOI, Pohang-si (KR)

(73) Assignee: POSTECH RESEARCH AND BUSINESS DEVELOPMENT FOUNDATION, Pohang-si (KR)

(21) Appl. No.: 19/015,435

(22) Filed: Jan. 9, 2025

(30) Foreign Application Priority Data
Jun. 7, 2024 (KR) 10-2024-0074242
Dec. 24, 2024 (KR) 10-2024-0196128

(51) Int. Cl. G02F 1/1335; G02F 1/1343

(52) U.S. Cl. CPC G02F 1/133541; G02F 1/133553; G02F 1/13439

(57) ABSTRACT

Provided is a circularly polarized light emitting display device including: a reflecting electrode; a light emitting element layer; a circular polarization layer; and a selective reflection layer provided between the light emitting element layer and the circular polarization layer, at least part of which is configured to have the same or opposite direction of rotation as or to the circular polarization layer. The circularly polarized light emitting display device. The circularly polarized light emitting display device can completely prevent reflection of external incident light and prevent a decrease in the light emission efficiency of an OLED.

### CROSS REFERENCE TO RELATED APPLICATIONS

This application claims priority to Korean Patent Application No. 10-2024-0074242 filed on Jun. 7, 2024 and No. 10-2024-0196128 filed on Dec. 24, 2024, the entire contents of each of which are hereby incorporated by reference in their entirety.

### BACKGROUND

### Field

The present disclosure relates to a circularly polarized light emitting display device capable of minimizing light loss.

### Description of Related Art

Light emitting display technologies such as OLEDs use circular polarizers in order to control the decrease in ambient contrast caused by display surface reflection of ambient light incident from the outside. Such circular polarizers are generally called “OLED polarizers” in the field of displays.

An OLED circular polarizer includes a linear polarizer and a quarter wave plate creating a phase retardation of one-fourth of a wavelength (λ) stacked together to convert linearly polarized light into right-handed circular polarized light (RCP) or left-handed circular polarized light (LCP). The QWP is placed at +45° or −45° angle relative to the linear polarizer. Also, a broadband circular polarizer (QWP) which works in a broader wavelength range may be configured by combining a linear polarizer, a QWP, and a half wave plate (HWP), in which case the QWP and the HWP are designed to be placed at 75° and 15°, respectively.

FIG. 1 shows the concept of an OLED to which a cross polarizer according to the related art is applied. Referring to FIG. 1, the circular polarizer converts unpolarized light incident from the outside into RCP or LCP, making it incident on the OLED display. This light is reflected as it passes through a reflecting electrode (positive electrode, negative electrode, etc.) inside the OLED. The reflected light re-passes through the QWP, creating a further phase retardation of ¼λ. As a result, the phase retardation (¼λ) created upon initial incidence and the further phase retardation (¼λ) created upon reflection are combined to form a ½λ phase retardation, which is converted into linear polarized light. In this case, the linearly polarized light is rotated by 90 degrees relative to the optical axis of the polarizer, and external light is completely prevented from being reflected due to the cross polarizer effect. By this, the OLED provides perfect black display by fully blocking external light, and maximizes display contrast and quality.

FIG. 2 shows another OLED structure according to the related art. Referring to FIG. 2, the conventional technology is problematic in that the light efficiency decreases to no more than 50% as the light passes through the circular polarizer. This is because light loss is inevitable in the linear polarizer placed over the QWP. Consequently, although external light reflection can be reduced, the light emitted from the OLED is lost after passing through a color filter, thereby decreasing the light emission efficiency to less than 50%.

To sum up, although the OLED circular polarizer is advantageous in that it completely prevents external light reflection, its crucial flaw is that the OLED has lower light emission efficiency. Such luminance loss shortens the overall lifetime of the OLED display and makes it difficult to overcome the dark screen issue.

### SUMMARY

The present disclosure is directed to providing a circularly polarized light emitting display device capable of achieving circular polarization by matching conventional OLED light emission to an OLED polarizer and improving light emission efficiency as the OLED light emission is matched to the OLED polarizer.

An exemplary embodiment of the present disclosure provides a circularly polarized light emitting display device including: a reflecting electrode; a light emitting element layer; a circular polarization layer; and a selective reflection layer provided between the light emitting element layer and the circular polarization layer, at least part of which is configured to have the same or opposite direction of rotation as or to the circular polarization layer.

Meanwhile, the selective reflection layer may be configured to have different transmissibility depending on the direction of rotation of light.

Meanwhile, the selective reflection layer may have a twisted chiral structure, and may include a chiral optical structure having a pitch of several tens or hundreds of nm.

Meanwhile, the chiral optical structure may have an optical effect of rotating incident light to the left or the right.

Moreover, the chiral optical structure may include a helical optical rotation structure.

Meanwhile, the chiral optical structure may be a chiral molecule, a liquid crystal having a refractive index anisotropy Δn, or a mesogenic molecule.

Meanwhile, the selective reflection layer may be configured in such a way that the reflection wavelength width (Δλ-chiral) of the chiral optical structure is greater than the emission wavelength width (Δλ-emission) of the light emitting element layer.

Furthermore, the position of the center wavelength of the reflection wavelength width of the chiral optical structure may include a wavelength position of 200 nm to 2,000 nm.

Meanwhile, the chiral optical structure may be configured to reflect light corresponding to a chiral photonic band gap reflection wavelength.

Meanwhile, the chiral optical structure may have a first directional rotation structure in which, of unpolarized incident light generated from the light emitting element layer, first direction circularly polarized light is reflected toward the light emitting element layer and second direction circularly polarized light which is opposite to the first direction is transmitted.

Furthermore, the circular polarization layer may be configured to have a left circular polarization property or a right circular polarization property so as to suppress reflection of external light, and to have at least one phase retardations relative to a linear polarizer.

Additionally, the circular polarization layer may have the second direction polarization property so that the second direction polarized light rotating in the same direction as the circularly polarized light of the circular polarization layer passes therethrough.

Meanwhile, the first direction polarized light, which is a circular polarization component rotating in the same direction as the chiral optical structure, may be reflected from the selective reflection layer, and the first direction polarized light may be converted into the second direction polarized light which rotates in the opposite direction to the chiral optical structure and is reflected from the reflecting electrode.

Meanwhile, the light whose direction of circular polarization is converted and which is reflected as the second direction polarized light may rotate in the opposite direction to the chiral optical structure and rotate in the same direction as anti-reflective circularly polarized light for which the linear polarizer and a phase retardation layer are stacked, and the light may be released by passing through the light emitting element layer, the selective reflection layer, and the circular polarization layer.

Moreover, the primary circularly polarized light generated from the light emitting element layer and secondary circularly polarized light reflected from the selective reflection layer and the reflecting electrode may be released at different times and combined together, and the combined circularly polarized light has the same direction of polarization rotation as a polarization anti-reflection layer of a circular polarizer including a linear polarizer and a phase retardation layer, thereby improving the light emission efficiency of the light emitting display without optical loss caused by the polarizer.

Additionally, the selective reflection layer may include a chiral liquid crystal layer so that refractive indices n1 and n2 appear repeatedly by rotation structure.

Meanwhile, the chiral layer may be produced by a process of giving the chiral structure left handed chirality and/or right handed chirality.

Meanwhile, the chiral layer may be configured in such a way that the force of rotation per unit length changes with changing temperature of the chiral structure, and the wavelength of reflected light becomes shorter or longer as the temperature of the chiral structure rises.

Meanwhile, the circularly polarized light emitting display may be composed of organic, inorganic, and organic-inorganic hybrid materials, quantum dots, a perovskite, a quantum nanowire, and an organic light emitting semiconductor, and has at least one polarizer.

Moreover, the circular polarizer may be configured to have a ¼ phase retardation (quarter wave retardation) relative to the linear polarizer, and may have a function of preventing reflection of light incident onto the light emitting display through crossed polarization which involves 90-degree rotation of linearly polarized light by a phase retardation (¼) which occurs when external light is reflected by the light emitting display and linear polarized light is finally incident and a reflection phase retardation (¼) which occurs upon reflection from the light emitting element, allowing the light emitting display to emit circularly polarized light.

Meanwhile, the circularly polarized light emitting display may further include a linear polarizer which is coupled to the circular polarizer.

Furthermore, the circular polarizer may include a linear polarizer and a ½ phase plate (half wave plate) so as to have a circular polarization function with a wide wavelength.

Meanwhile, the chiral layer may be formed integrally with the light emitting element layer.

Also, the chiral layer may be formed integrally with the circular polarization layer.

Meanwhile, the chiral layer may include a UV-curable material.

Meanwhile, the chiral layer may be manufactured by patterning by a photolithography process using a photo mask.

Meanwhile, the chiral layer may include a monoacrylate or diacrylate molecular structure, or may include epoxy, epoxy acrylate, or a thiol to induce a polymer curing reaction with visible light or UV light, or may include a decomposable component.

Meanwhile, the chiral layer may be configured in such a way that the chiral structure has a different pitch for each pixel.

Meanwhile, the chiral structure may have at least two pitches, and may be cured and fixed at different temperatures for the two pitches.

Furthermore, the chiral layer may be 100 nm to 10 mm.

Meanwhile, a plurality of chiral layers may be provided.

Meanwhile, each chiral layer may have a different reflection wavelength width.

Meanwhile, each chiral layer may have the same chirality as or opposite chirality to the chiral structure.

Meanwhile, the circular polarization layer may have the same polarization orientation as at least one of the plurality of chiral layers.

Moreover, the chiral layer may be provided for each pixel of the light emitting element, and may have a different size for at least one pixel.

Additionally, the chiral layer may be composed of a layer configured to form a photopattern caused by light through the above process and adjust the circular polarization characteristics of the same color or different colors.

A circularly polarized light emitting display device according to the present disclosure has the effect of completely preventing the reflection of external incident light and preventing a decrease in the light emission efficiency of an OLED.

### BRIEF DESCRIPTION OF THE DRAWINGS

FIG. 1 shows the concept of an OLED to which a cross polarizer according to the related art is applied.

FIG. 2 is a view illustrating another example of an OLED structure according to the related art.

FIG. 3A is a cross-sectional view of a pixel in a circularly polarized light emitting display device according to a first embodiment of the present disclosure.

FIG. 3B is a cross-sectional view of a pixel in a modified example of a circularly polarized light emitting display device according to the first embodiment of the present disclosure.

FIG. 3C is a cross-sectional view of a pixel in another modified example of a circularly polarized light emitting display device according to the first embodiment of the present disclosure.

FIGS. 4A and 4B are conceptual diagrams illustrating optical chirality according to the first embodiment of the present disclosure.

FIG. 5 is a conceptual diagram illustrating the concept of rotation of a chiral structure in the present disclosure.

FIG. 6A is a conceptual diagram illustrating a path of primary light provided by a chiral layer according to a second embodiment of the present disclosure.

FIG. 6B is a conceptual diagram illustrating a path of secondary light provided by the chiral layer according to the second embodiment of the present disclosure.

FIG. 6C is a conceptual diagram illustrating a final path of secondary light provided by the chiral layer according to the second embodiment of the present disclosure.

FIG. 7 is a conceptual diagram illustrating a chiral structure according to an embodiment of the present disclosure.

FIGS. 8A, 8B, 8C, and 8D are views illustrating the concept of a process of generating a chiral layer in a circularly polarized light emitting display device according to another embodiment of the present disclosure.

FIG. 9 is a view illustrating the concept of forming a chiral layer by a photolithography process.

FIG. 10 is a view illustrating an example of a molecular structure of a chiral structure according to another embodiment of the present disclosure.

FIG. 11 is a view illustrating pitches of liquid crystal molecules in the chiral layer according to an embodiment of the present disclosure.

FIG. 12 is a graph illustrating the wavelength of light relative to temperature that is selectively reflected from chiral liquid crystals.

FIG. 13 is a graph illustrating a change in the pitch of a chiral structure relative to temperature.

FIG. 14 is a conceptual diagram showing an optical path for a circularly polarized light emitting display device according to an embodiment of the present disclosure.

FIG. 15 is a conceptual diagram illustrating a modified example of a pattern of the chiral layer according to another embodiment of the present disclosure.

FIG. 16 is a conceptual diagram illustrating another modified example of a pattern of the chiral layer according to another embodiment of the present disclosure.

FIG. 17 is a conceptual diagram showing a structure of a vertically stacked OLED (Tandem OLED).

FIG. 18 is a graph illustrating multiple chiral layers and a reflection wavelength according to one embodiment of the present disclosure.

FIG. 19 is a graph illustrating multiple chiral layers and a reflection wavelength according to another embodiment of the present disclosure.

FIG. 20 is a conceptual diagram illustrating a molecular structure included in a chiral layer according to another embodiment of the present disclosure.

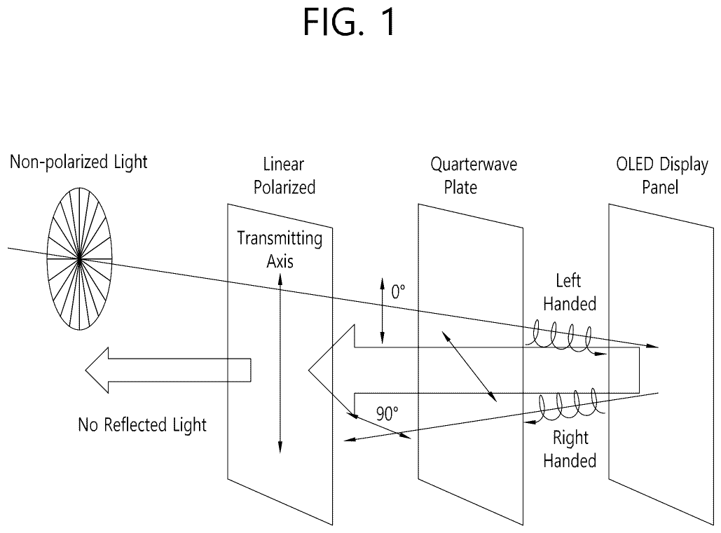

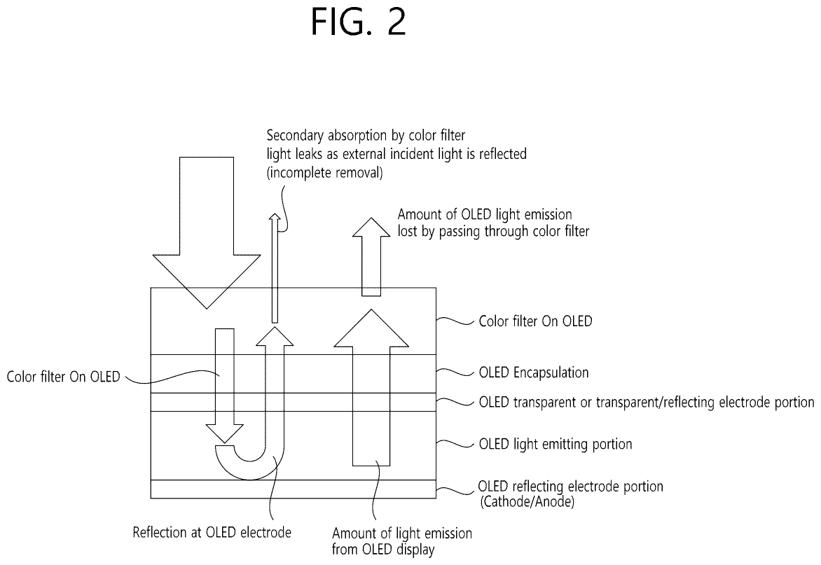

### DETAILED DESCRIPTION

Hereinafter, a circularly polarized light emitting display device according to embodiments of the present disclosure will be described in detail with reference to the attached drawings. In description of the following embodiments, the name of each component may be referred to as different names in the art. However, if there is functional similarity and identity between components, they can be regarded as equivalent components even if modified embodiments are adopted. Additionally, a symbol is attached to each component for convenience of description. However, content shown in the drawings in which such symbols are written does not limit each component to the scope within the drawings. Likewise, even if an embodiment in which a configuration in a drawing is partially modified is adopted, it can be regarded as an equivalent configuration if there is functional similarity and identity. Further, if a component is recognized as a component that should be included in light of the general level of technicians in the relevant technical field, the description thereof will be omitted.

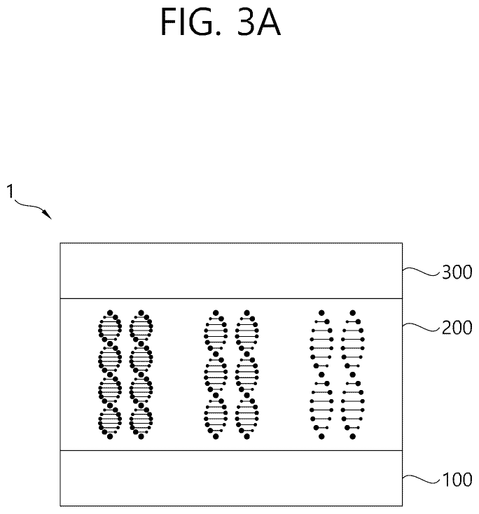

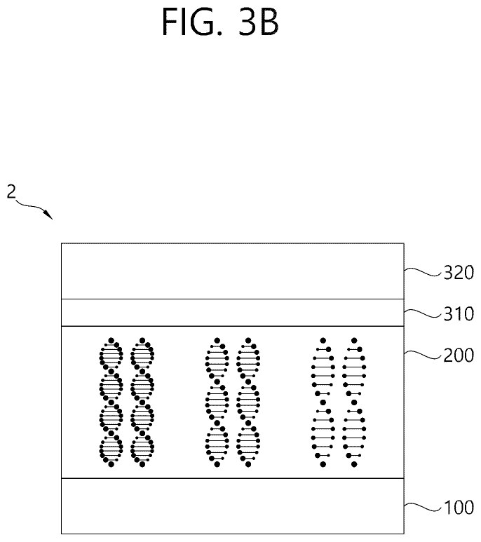

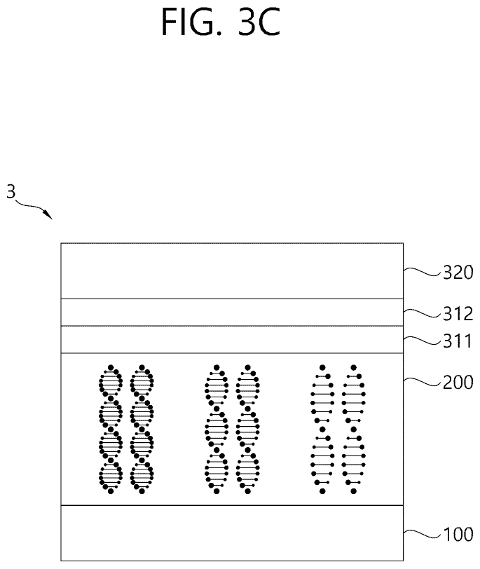

FIG. 3A is a cross-sectional view of a pixel in a circularly polarized light emitting display device according to a first embodiment of the present disclosure.

Referring to FIG. 3A, a circularly polarized light emitting display device according to the first embodiment of the present disclosure may include a light emitting part 100, a chiral layer 200, and a circular polarization layer.

In this disclosure, the light emitting part 100 may refer to an OLED or other light emitting display. The light emitting part 100 may include one or more reflecting electrodes 100 in order to efficiently release light.

The reflecting electrode 110 may contribute to optimizing display performance by reflecting emitted light in a particular direction. In this case, the reflected light may be circularly polarized in the opposite direction.

The chiral layer 200 may include a rotationally symmetrical structure (chiral structure) of a nanometer size corresponding to the wavelength of light. In this disclosure, the chiral structure may form a rotational structure as it is twisted to the left or the right. The chiral structure serves to manipulate a circular polarization component of light and exhibits the optical activity related to the chirality of light. The chiral layer 200 is a selective reflection layer, which is configured to reflect light of a selective wavelength. The twisted chiral structure 200 may have a pitch of several tens or hundreds of nm.

The circular polarization layer is configured to allow polarized light of one direction to selectively pass therethrough and block the rest of the light. In this embodiment, the circular polarization layer may include a circular polarizer. The circular polarizer is configured to improve the contrast and efficiency of the display by controlling reflections of light emitted from the OLED and external light.

In this disclosure, the chiral layer 200 may be provided between the circular polarizer and the light emitting part 100 to improve contrast and light emission efficiency. Also, it may completely block light incident from the outside. Moreover, in this disclosure, the chiral layer 200 may have a thickness of 100 nm to 10 mm.

FIG. 3B is a cross-sectional view of a pixel in a modified example of a circularly polarized light emitting display device according to the first embodiment of the present disclosure. FIG. 3C is a cross-sectional view of a pixel in another modified example of a circularly polarized light emitting display device according to the first embodiment of the present disclosure.

Referring to FIG. 3B, in the modified example of the circularly polarized light emitting display device according to the first embodiment of the present disclosure, the circular polarization layer may include a linear polarizer 320 and a phase retardation plate 310, and may be configured to block light in a particular direction. Specifically, the circular polarization layer may be configured to have a ¼ phase retardation (quarter wave retardation) relative to the linear polarizer 320. A phase retardation (¼) may occur when external light is reflected from the reflecting electrode 110 in the light emitting display, and a reflective phase retardation (/14) may occur when the light is reflected from a light emitting element 120. Accordingly, reflection of light incident on the light emitting display may be prevented through crossed polarization which involves 90-degree rotation of linearly polarized light.

Referring to FIG. 3C, in the modified example of the circularly polarized light emitting display device according to the first embodiment of the present disclosure, the circular polarization layer may include a linear polarizer 320, a QWP 312, and a HWP 311. Accordingly, external incident light may be blocked at the circular polarization layer according to the reflective phase retardation within the light emitting layer.

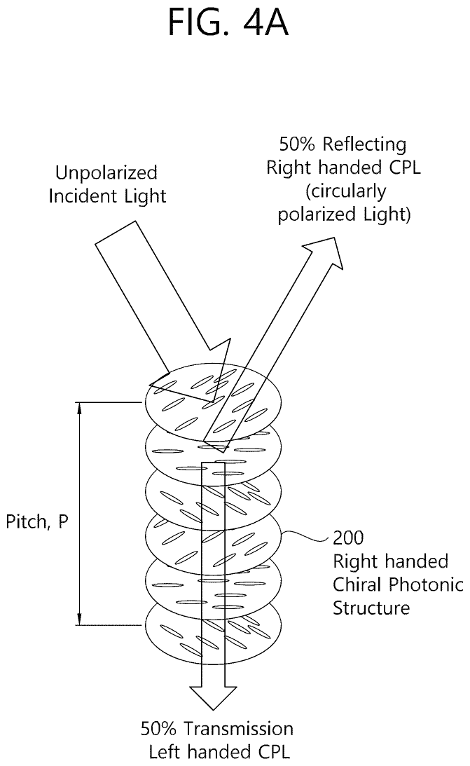

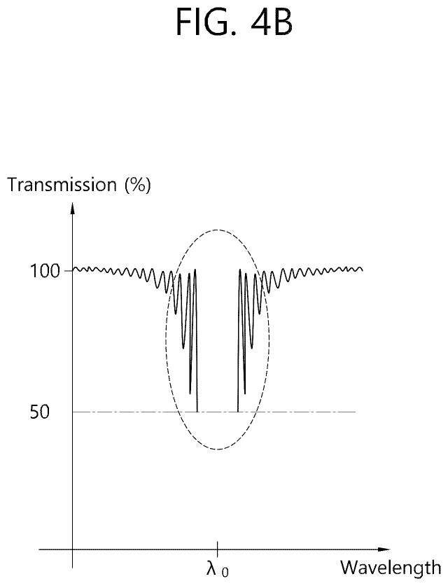

FIGS. 4A and 4B are conceptual diagrams illustrating optical chirality according to the first embodiment of the present disclosure.

Referring to FIG. 4A, a chiral photonic structure (CPS) 200 is configured as a helical dielectric structure in which light is several hundreds of nanometers in wavelength, and is characterized in that it selectively controls chiral components of light. For example, if the chiral photonic structure has a right-handed chiral component, unpolarized light is divided into two components when it meets this structure.

Right circular polarization (RCP) which occupies about 50% of the unpolarized light is reflected by the chiral structure and returns toward the original direction, and left circular polarization (LCP) which occupies the remaining 50% continues to pass through the chiral structure. In this process, the chiral structure serves as a selective filter that reflects the component (RCP) which rotates in the same direction as the chiral structure and passes the oppositely oriented component LCP therethrough without limitation. The reflected light component is right handed CPL (circularly polarized light). Conversely, the transmitted light is left handed CPL.

Referring to FIG. 4B, a wavelength region in which the chiral components are selectively controlled according to the pitch of the chiral structure may be determined. Depending on the pitch of the chiral structure, part of light is reflected in a certain region Δλ, and the rest is passed through. In this case, the transmitted light and the reflected light may be opposite to each other in chirality.

Moreover, this structure has no absorption and loss of light energy since it does not include a color filter or an absorbing dye. As a result, the maximum light energy is preserved without a decline in efficiency caused by absorption in the reflection and transmission processes.

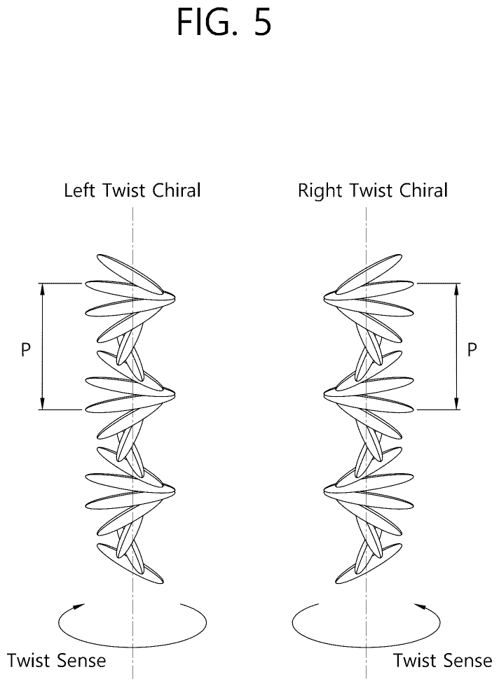

FIG. 5 is a conceptual diagram illustrating the concept of rotation of a chiral structure in the present disclosure.

Referring to FIG. 5, the chiral structure may be formed as a left handed structure or a right handed structure.

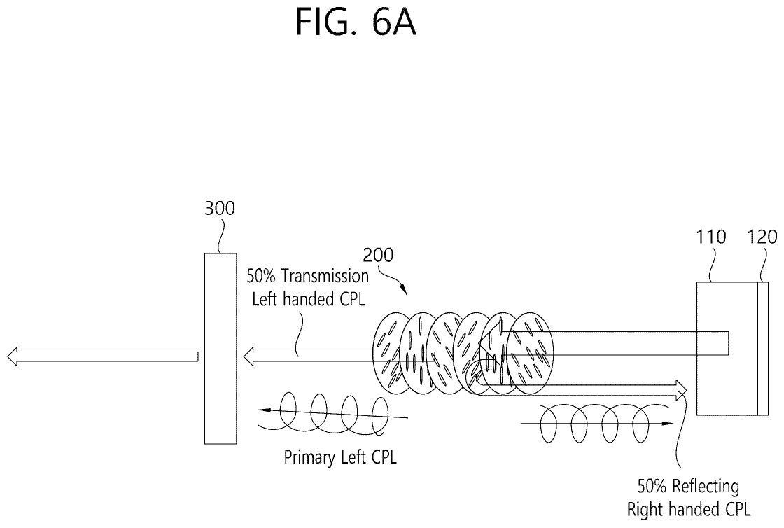

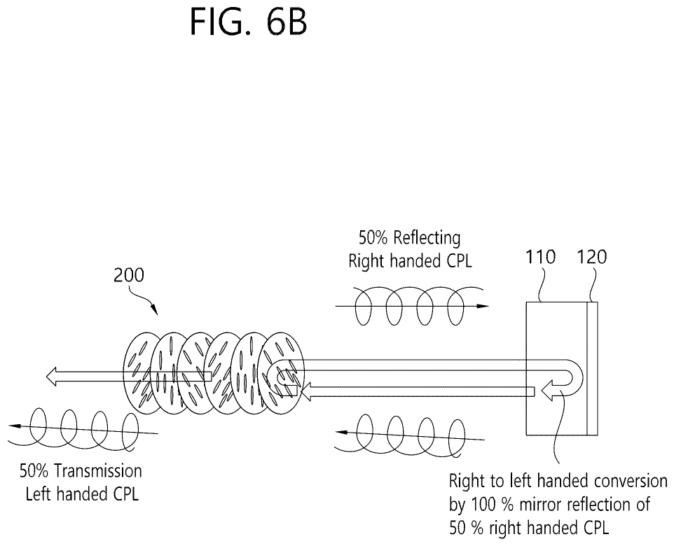

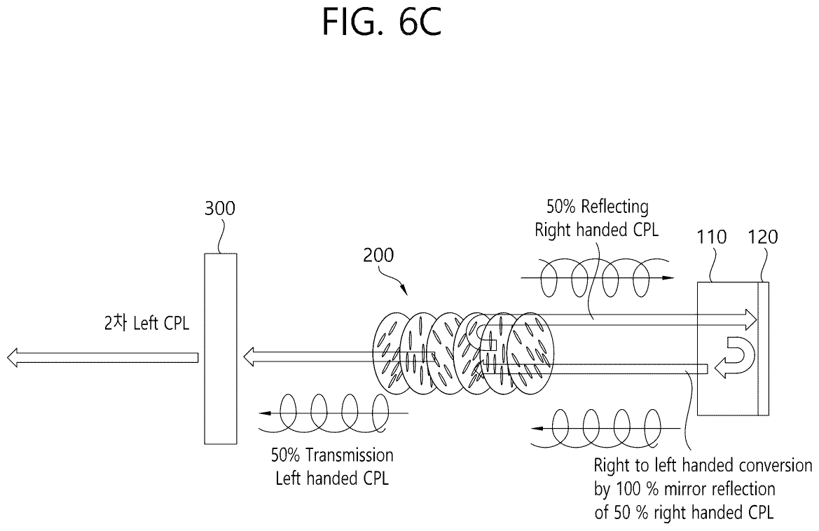

FIG. 6A is a conceptual diagram illustrating a path of primary light provided by a chiral layer according to a second embodiment of the present disclosure.

Referring to FIG. 6A, in the second embodiment of the present disclosure, the circular polarizer is configured to achieve left circular polarization, and the chiral layer 200 may include a right handed chiral structure.

The light emitting part 100 may include one or more light emitting elements 120 and one or more reflecting electrodes 110. The chiral layer 200 may be provided above the light emitting part 100. Since the chiral layer 200 includes a right handed chiral structure, unpolarized light emitted from the OLED (unpolarized OLED emission) is divided into two by interaction with the chiral structure.

First, in a process in which unpolarized OLED light passes through the right handed chiral structure (R-chiral), the right circular polarization (RCP) which rotates in the same direction as the chiral structure is reflected by the chiral structure. The reflected RCP component does not pass through the chiral structure but returns into the OLED and is re-used.

In contrast, the left circular polarization (LCP) which rotates in the opposite direction to the chiral structure passes through the chiral structure and travels toward the polarizer 300. The RCP component of the emitted light is re-used, and only the LCP component is transmitted and finally delivered to the outside of the display.

In this case, the 50% left circular polarization (LCP) passed through the right handed chiral structure is matched to the left circular polarizer placed at the polarizer 300, and finally passes through the chiral structure while preserving 50% light emission efficiency without loss in the polarizer 300.

In this case, when primary light that passes through a left handed circular polarizer is referred to as a primary left handed light component (CPL), the primary left handed light component is transmitted without loss since it rotates in the same direction as the circular polarizer 310, and the light of the opposite chirality to the primary left handed light component is blocked from being transmitted.

FIG. 6B is a conceptual diagram illustrating a path of secondary light provided by the chiral layer 200 according to the second embodiment of the present disclosure.

Referring to FIG. 6B, first, the 50% right circular polarization (RCP) which is reflected from the right hand chiral structure (R-chiral) and returns into the OLED is reflected 100% by the reflecting electrode 110 inside the OLED and transmitted. In this case, in the reflection process, RCP is entirely converted into left circular polarization (LCP).

The LCP obtained through phase inversion by reflection is incident back on the right handed chiral structure (R-chiral), and the R-chiral allows for reflecting the right handed circular polarization (RCP) rotating in the same direction as the R-chiral, and allows the left handed circular polarization (LCP) rotating in the opposite direction to be passed therethrough without absorption. As a result, the LCP obtained through the reflection passes through the R-chiral without loss, and the circularly polarized light is efficiently re-used.

FIG. 6C is a conceptual diagram illustrating a final path of secondary light provided by the chiral layer 200 according to the second embodiment of the present disclosure.

Referring to FIG. 6C, the left circular polarization (LCP) which is retro-reflected after passing through the R-chiral finally passes through a left circular OLED polarizer. In this case, secondary LCP light is finally obtained without loss as circular polarization is matched to the LCP circular polarizer

Accordingly, the overall OLED luminance becomes higher in efficiency through secondary LCP emission in addition to the primary LCP emission, and the light generated initially from the OLED is all used for the entire OLED luminance. Theoretically, in the context of loss in the conventional OLED circular polarizer, the light emission efficiency may be increased up to twice that of the conventional art.

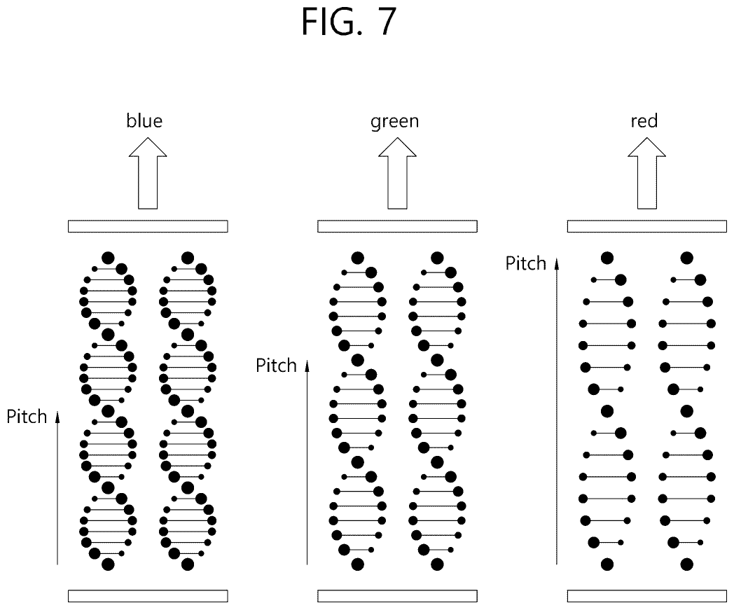

FIG. 7 is a conceptual diagram illustrating a chiral structure according to an embodiment of the present disclosure.

Referring to FIG. 7, the chiral photonic structure is adjusted by adjusting the pitch p of a chiral helix, or is adjusted to match the emission wavelength of a particular OLED and light emitting element, through the refractive index and anisotropy Δλ of birefringence liquid crystal material and other mesogenic (birefringent) materials. This adjustment may correspond to a variety of emission wavelengths such as yellow/green, orange, etc. as well as red, green, and blue.

As for color wavelengths to which retro-reflected and circularly polarized light is filtered, the center wavelength λc and the wavelength width λΔ are adjusted to match the emission wavelength of emitted light. In this case, the following equations are given:

$$Position of center wavelength : λ c = navg \cdot p \qquad ( Equation 1 )$$

$$Photonic band gap ( wavelength width ) : Δλ = Δ n \cdot p \qquad ( Equation 2 )$$

$$Navg is the average value of refractive indices n 1 an n 2 : \qquad ( Equation 3 )$$

$$navg = ( n 1 + n 2 ) / 2$$

$$Δ n is the difference between n 1 and n 2 : Δ n = n 1 - n 2 \qquad ( Equation 4 )$$

Through these equations, the characteristics of the chiral photonic structure may be adjusted to optimize the color and efficiency of the light emitting element.

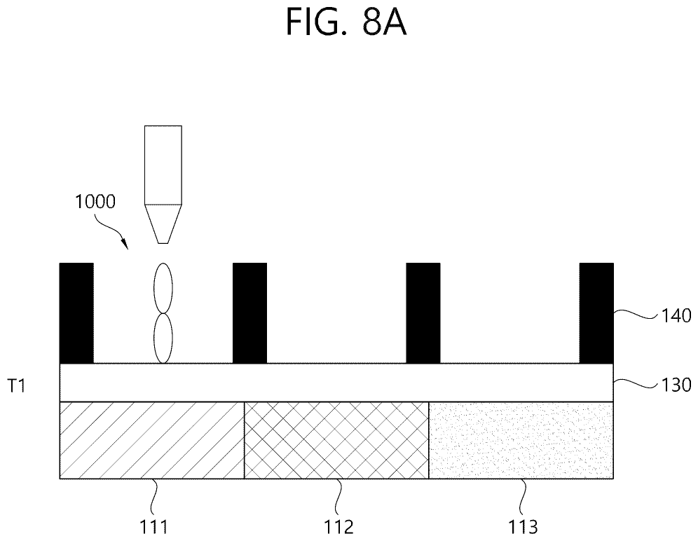

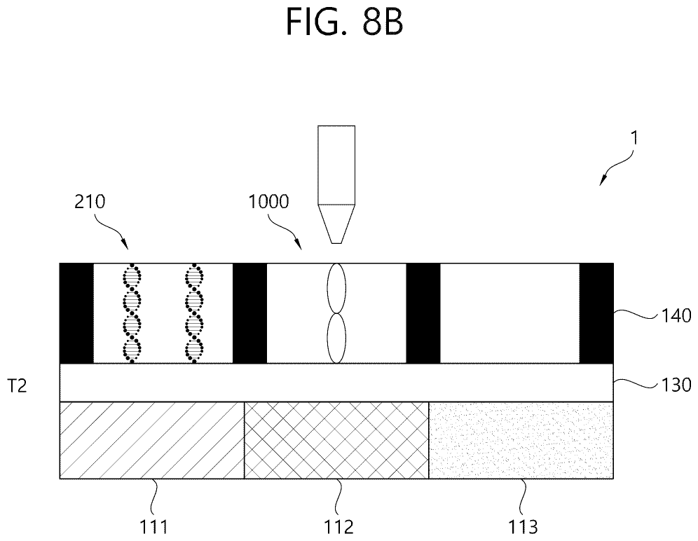

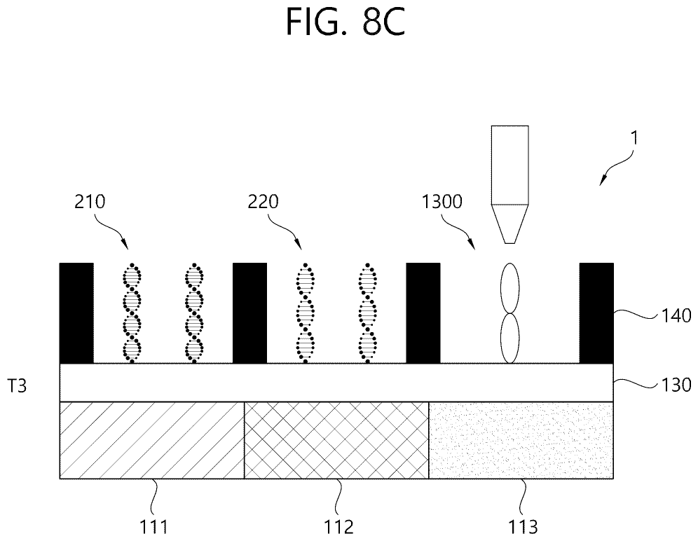

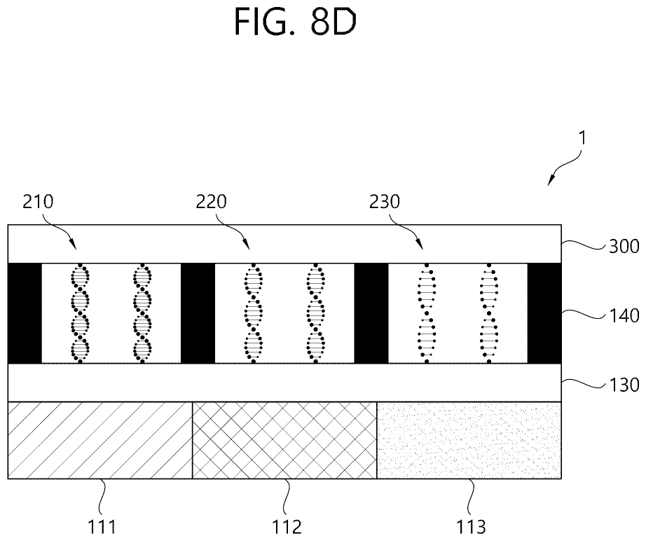

FIGS. 8A, 8B, 8C, and 8D are views illustrating the concept of a process of generating chiral layers 210, 220, and 230 in a circularly polarized light emitting display device according to another embodiment of the present disclosure.

In this disclosure, the display may generate sub-pixels and an encapsulation layer 130 and then form a chiral layer. The chiral layer may be generated in each sub-pixel by forming a black bank 130 at R/G/B subpixels and then curing a chiral liquid crystal layer whose pitch and chirality are adjusted.

Referring to FIG. 8A, the first chiral layer 210 may be cured after adjusted to have the longest pitch in order to amplify blue light. In this case, the material 1000 may be applied to a position corresponding to a blue light emitting element 111 after adjusted to a first temperature T1.

Referring to FIG. 8B, the second chiral layer 220 may be formed at a position corresponding to a green light emitting element 112 in order to amplify green light. In this case, the material 1000 may be applied and cured after adjusted to a second temperature T2 so as to have an intermediate pitch.

Referring to FIG. 8C, the third chiral layer 230 may be formed at a position corresponding to a red light emitting element 113 in order to amplify red light. In this case, the material 1000 may be applied and cured after adjusted to a third temperature T3 so as to have an intermediate pitch.

Referring to FIG. 8D, the chiral twist pitch of chiral liquid crystals in each chiral layer 210, 220, and 230 may remain fixed. Needless to say, the amount of change in pitch relative to temperature may be taken into account when the temperature is adjusted to a room temperature or working temperature, and the chiral pitch of liquid crystals may be determined by compensating for the change in advance. Afterwards, the circular polarizer 300 may be provided on an outer side of the chiral layers 210, 220, and 230. In this case, the chirality of the circular polarizer may be opposite to that of the chiral structure.

Meanwhile, ink for forming the first chiral layer 210, the second chiral layer 220, and the third chiral layer 230 may be the same material. However, each chiral layer 210, 220, and 230 may be adjusted to a predetermined temperature and cured by UV, so as to adjust the pitch of the chiral liquid crystals. In this case, the first chiral layer 210 which amplifies blue light may be cured after adjusted to the highest temperature. Next, the second chiral layer 220 which amplifies green light may be cured after adjusted to a temperature lower than the first chiral layer 210. Lastly, the third chiral layer 230 which amplifies red light may be cured after adjusted to the lowest temperature.

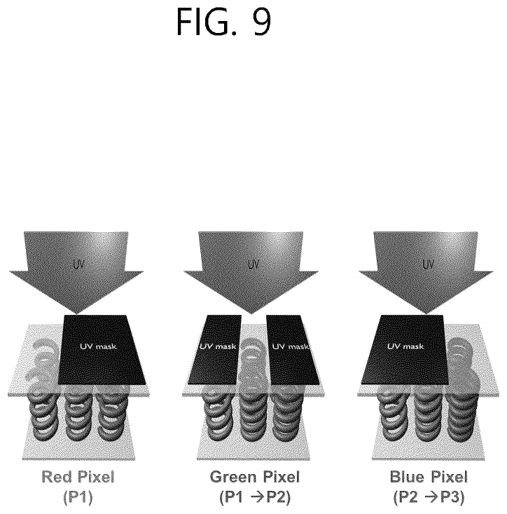

FIG. 9 is a view illustrating the concept of forming a chiral layer 200 by a photolithography process.

Referring to FIG. 9, in the present disclosure, each chiral layer may be formed in a geometric pattern at each of a large number of pixels. A material constituting a selective reflective layer of the chiral LC of the chiral layer may be adjusted to have a UV-curable, chain-forming molecular structure and a predetermined direction of rotation and applied as a coating, and positions (red pixel and green pixel) where blue selective reflection is desired may be exposed to light through an exposure mask, thereby forming a curable CLC layer for selectively amplifying blue light only at a selective position. Afterwards, the chiral layer may be formed only at a desired position by washing a region that is not cured with UV by a development process by blocking a mask pattern.

Also, each chiral layer may be formed through a UV curing pattern using a UV curing structure and a desired mask. In this case, the chiral structure whose direction of rotation is predetermined may be formed at a position corresponding to each of R/G/B by adjusting the pitch by inducing a change in pitch relative to temperature.

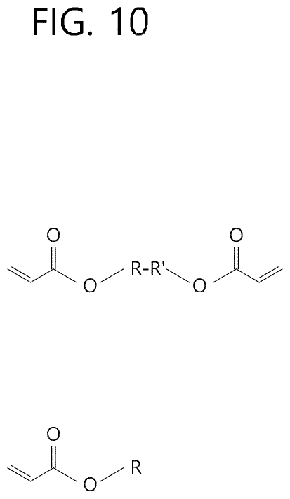

FIG. 10 is a view illustrating an example of a molecular structure of a chiral structure according to another embodiment of the present disclosure.

Referring to FIG. 10, a material constituting a selective reflective layer of the chiral layer (chiral LC) 200 may be generated as a material including a UV-curable, chain-forming molecular structure. The material constituting the chiral layer 200 may include a monoacrylate or diacrylate molecular material having one or more UV-curable acrylate reaction groups. In this case, the molecular material has a bonding structure “R” capable of all various types of birefringence, and the molecules of R may include any of all other reaction bonding structures including a phenyl group, a hexagonal group, a methyl group, an ester group, an ether group, etc.

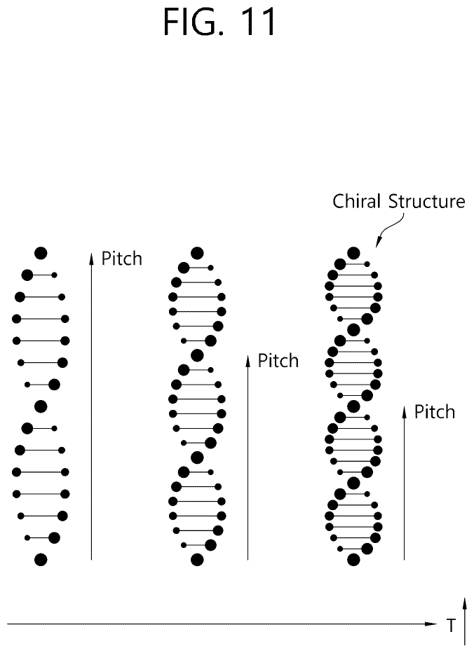

FIG. 11 is a view illustrating pitches of liquid crystal molecules in a chiral layer according to an embodiment of the present disclosure.

Referring to FIG. 11, the liquid crystal molecules in the chiral layer may reflect light at different wavelengths depending on the length of a helical chiral structure

Specifically, if the length of the helical chiral structure of birefringence molecules is varied, the reflection wavelength may be varied according to the De Vries condition: Δλ=Δn·p (Δλ: wavelength range of light representing a color that is selectively reflected, Δn: difference in refractive index (n1−n2), p: repeat length of chiral pitch).

Meanwhile, the force of rotation per unit thickness of the chiral layer (d/p where d is the unit thickness of a chiral LC helical structure and p is the repeat cycle of helical chiral twists of CLC molecules) increases with increasing temperature. Accordingly, the repeat cycle of helical chiral twists of CLC molecules may be adjusted by inducing a temperature change, and as a result, the wavelength of amplified light may be adjusted.

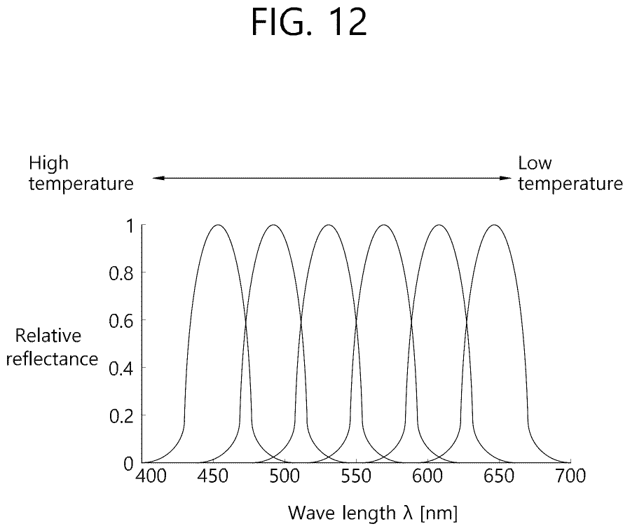

FIG. 12 is a graph illustrating the wavelength of light relative to temperature that is selectively reflected from chiral liquid crystals.

Referring to FIG. 12, a color conversion layer may induce a decrease in chiral pitch P at a CLC layer having a unit thickness d at a high temperature. By inducing a change ΔT toward an increase in temperature, the chiral length of CLC liquid crystals is adjusted directly as the force of rotation d/p continuously increases. As a result, as the temperature increases, the chiral layer shows a tendency in which the selective reflection wavelength under the De Vries condition is adjusted toward blue wavelengths.

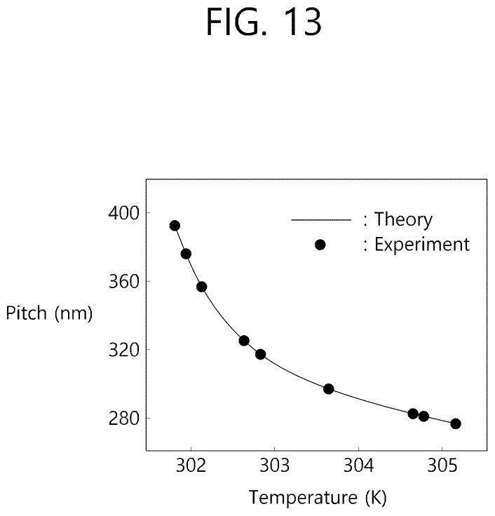

FIG. 13 is a graph illustrating a change in the pitch of a chiral structure relative to temperature.

Referring to FIG. 13, the chiral structure has high viscosity in a smectic phase and lower viscosity in a nematic phase. With increasing temperature, the chiral structure has lower viscosity and higher force of rotation per unit length as it is transitioned into a nematic phase. Accordingly, the pitch of the chiral structure becomes shorter as the temperature rises.

In contrast, with decreasing temperature, the pitch of the helical structure becomes longer as the chiral structure is transitioned from the nematic phase to the smectic phase.

As a result, the chiral structure allows for adjusting the De Vries condition Δλ=Δn·p (ΔλX: wavelength range of light representing a color that is selectively reflected, Δn: difference in refractive index (n1−n2), p: repeat length of chiral pitch) according to changes in temperature.

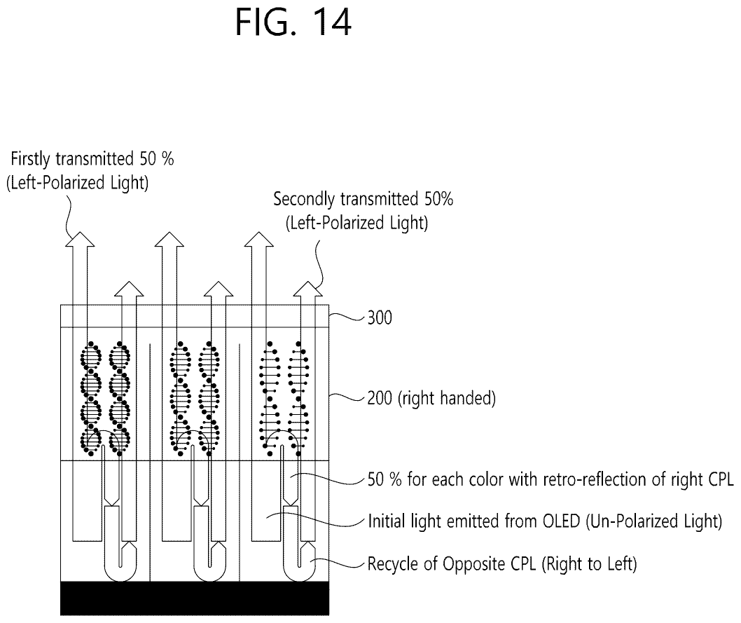

FIG. 14 is a conceptual diagram showing an optical path for a circularly polarized light emitting display device according to an embodiment of the present disclosure.

Referring to FIG. 14, in a chiral structure having a direction of rotation, light of a specific wavelength may be selectively adjusted to match a color such as red, green, and blue by adjusting the pitch (chiral length). Supposing that a right-handed chiral structure is constructed in this process, 50% of the light emitted from the light emitting element 120 is released to the outside as left circular polarization (left CPL) firstly through the chiral layer 200 and the polarizer 300.

In this case, the emitted light is reflected as it passes through the right-handed chiral structure 200. The reflected 50% right CPL returns to the OLED and is reflected like a mirror by the reflecting electrode 110 inside the OLED. In this case, the reflected right CPL is converted back to left CPL. Afterwards, the light converted to the left CPL efficiently reinforces the existing light by secondly passing through the chiral layer 200 having a right-handed chiral structure and the polarizer 300.

By repeating this process, 50% of the light corresponding to red, green and blue is converted to left CPL, in addition to the first left CPL, thus ultimately and ideally achieving 100% left CPL.

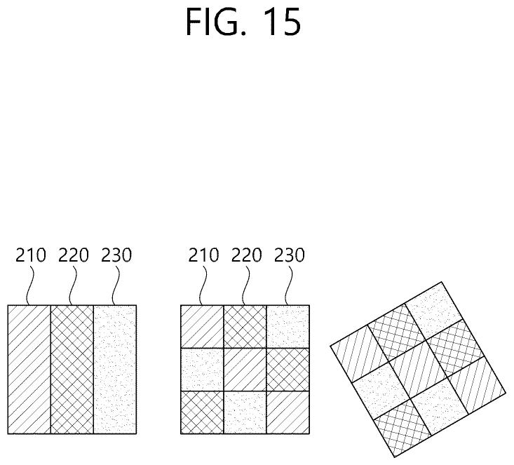

FIG. 15 is a conceptual diagram illustrating a modified example of a pattern of the chiral layer 200 according to another embodiment of the present disclosure.

Referring to FIG. 15, chiral layers may be generated by changing the pitch to various lengths by changing the temperature of one type of element and fixing memory by forming a mask pattern only at a desired position. Accordingly, when the generated display device is restored to a room temperature where it operates, chiral structures of various colors can be formed all at once. Also, the first chiral layer 210, the second chiral layer 220, and the third chiral layer 230 may be generated by changing the direction they are oriented.

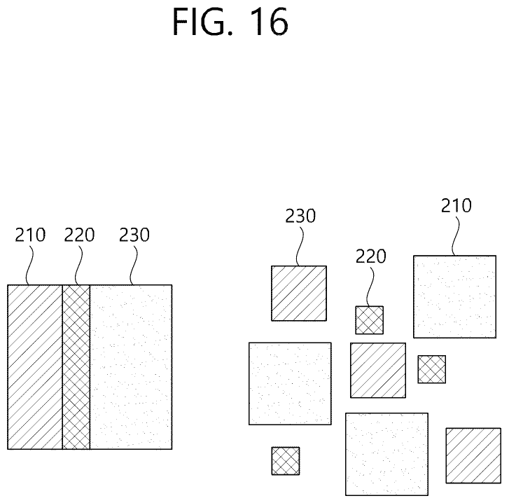

FIG. 16 is a conceptual diagram illustrating another modified example of a pattern of the chiral layer according to another embodiment of the present disclosure.

Referring to FIG. 16, in general, the efficiency of light emitted from an OLED differs in the order: Blue<Red<Green. Accordingly, the pixel size of the light emitting element may be varied in the order: Blue>Red>Green, and the chiral layers 210, 220, and 230 may be varied in size. This enables formation of a photo pattern using light.

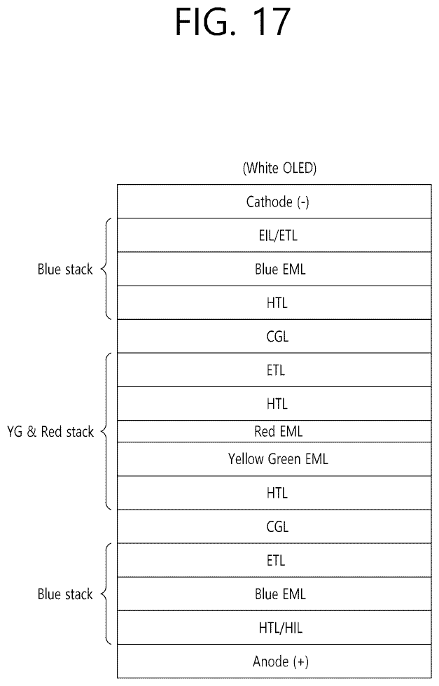

FIG. 17 is a conceptual diagram showing a structure of a vertically stacked OLED (Tandem OLED).

Referring to FIG. 17, a chiral layer according to the present disclosure may be applied not to the aforementioned R/G/B split light but to the vertically stacked OLED.

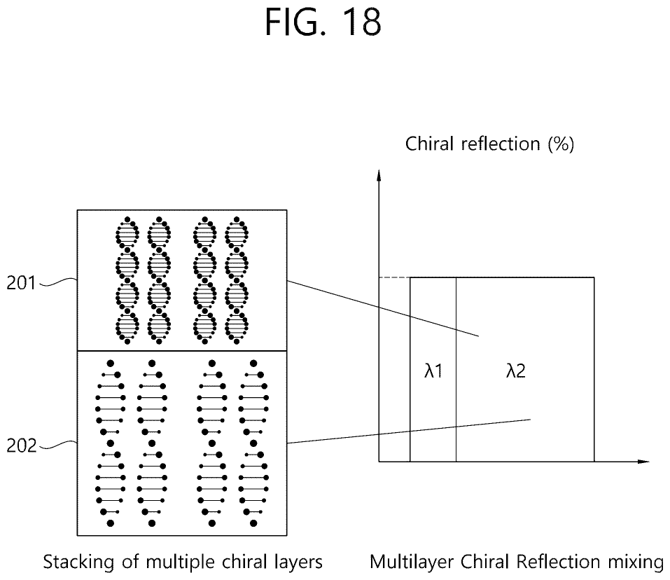

FIG. 18 is a graph illustrating multiple chiral layers and a reflection wavelength according to one embodiment of the present disclosure.

Referring to FIG. 18, a chiral structure P1 with a short pitch and a chiral structure with a long pitch P2 are combined to form a hetero tandem structure in which a chiral retro reflection λ1 of a short wavelength and a chiral retro reflection λ2 of a long wavelength are formed. By this, the chiral retro reflection λ1 of a short wavelength and the chiral retro reflection λ2 of a long wavelength are combined, thereby forming a chiral reflective structure corresponding to a white region of the full visible light range.

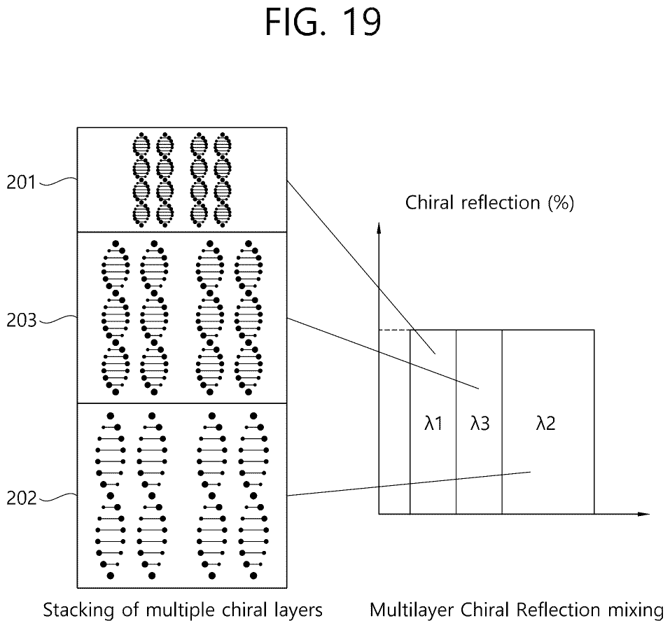

FIG. 19 is a graph illustrating multiple chiral layers and a reflection wavelength according to another embodiment of the present disclosure.

Referring to FIG. 19, the hetero chiral structure may be composed of three or more layers in order to sufficiently obtain and precisely configure white characteristics of a full visible light range. For example, if the hetero chiral structure is composed of three layers, an intermediate wavelength 23 with an intermediate pitch P3 is added, in addition to a short wavelength λ1 with a short pitch P1 and a long wavelength λ2 with a long pitch P2, thereby forming a white full visible light reflection layer.

The chiral layers 200 may be arbitrarily stacked in various sequences such as P1/P2/P3, P1/P3/P2, P2/P1/P3, P2/P3/P1, P3/P2/P1, and P3/P1/P2. If there are three or more chiral pitches, the stacking sequence may be arbitrarily selected by using all combinations of P1, P2, P3, . . . , Pn. In this way, optimum reflection characteristics may be achieved through various tandem chiral structures.

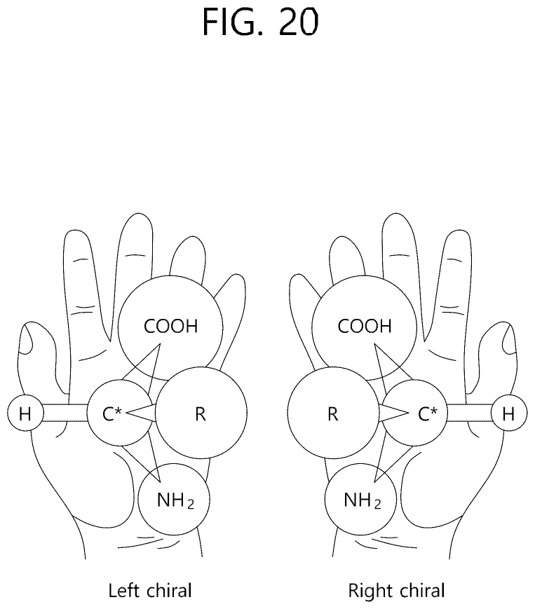

FIG. 20 is a conceptual diagram illustrating a molecular structure included in a chiral layer 200 according to another embodiment of the present disclosure.

Referring to FIG. 20, in the present disclosure, a chiral material included in the chiral layer 200 may be formed around an asymmetric carbon atom indicated by C*. atoms with different electrongativties are bonded around this C* atom, thereby creating a structure where the arrangement of electronegativities is not symmetric. Due to this structural characteristic, the chiral material may exhibit optical chirality. This chiral effect occurs in such a way that the chiral material includes a chiral compound, and at least one chiral compound should be present.

In this case, the chiral compound may have one of two types of chirality depending on the arrangement of atoms around the C* atom. That is, the compound may include a composition in which it may have the chiral characteristics of either the right-handed chiral or the left-handed chiral.

As explained above, a circularly polarized light emitting display device according to the present disclosure is capable of blocking external light incident on the display and maximizing the light emission efficiency of light generated from the light emitting element 120.

1. A circularly polarized light emitting display device comprising:
a reflecting electrode;
a light emitting element layer;
a circular polarization layer; and
a selective reflection layer provided between the light emitting element layer and the circular polarization layer, at least part of which is configured to have the same or opposite direction of rotation as or to the circular polarization layer.

2. The circularly polarized light emitting display device of claim 1, wherein the selective reflection layer is configured to have different transmissibility depending on the direction of rotation of light.

3. The circularly polarized light emitting display device of claim 2, wherein the selective reflection layer has a twisted chiral structure, and includes a chiral optical structure having a pitch of several tens or hundreds of nm.

4. The circularly polarized light emitting display device of claim 3, wherein the chiral optical structure has an optical effect of rotating incident light to the left or the right.

5. The circularly polarized light emitting display device of claim 4, wherein the chiral optical structure includes a helical optical rotation structure.

6. The circularly polarized light emitting display device of claim 5, wherein the chiral optical structure is a chiral molecule, a liquid crystal having a refractive index anisotropy Δn, or a mesogenic molecule.

7. The circularly polarized light emitting display device of claim 6, wherein the selective reflection layer is configured in such a way that the reflection wavelength width (Δλ-chiral) of the chiral optical structure is greater than the emission wavelength width (Δλ-emission) of the light emitting element layer.

8. The circularly polarized light emitting display device of claim 7, wherein the position of the center wavelength of the reflection wavelength width of the chiral optical structure includes a wavelength position of 200 nm to 2,000 nm.

9. The circularly polarized light emitting display device of claim 4, wherein the chiral optical structure is configured to reflect light corresponding to a chiral photonic band gap reflection wavelength.

10. The circularly polarized light emitting display device of claim 9, wherein the chiral optical structure has a first directional rotation structure in which, of unpolarized incident light generated from the light emitting element layer, first direction circularly polarized light is reflected toward the light emitting element layer and second direction circularly polarized light which is opposite to the first direction is transmitted.

11. The circularly polarized light emitting display device of claim 10, wherein the circular polarization layer is configured to have a left circular polarization property or a right circular polarization property so as to suppress reflection of external light, and to have at least one phase retardation relative to a linear polarizer.

12. The circularly polarized light emitting display device of claim 9, wherein the circular polarization layer has the second direction polarization property so that the second direction polarized light rotating in the same direction as the circularly polarized light of the circular polarization layer passes therethrough.

13. The circularly polarized light emitting display device of claim 10, wherein the first direction polarized light, which is a circular polarization component rotating in the same direction as the chiral optical structure, is reflected from the selective reflection layer, and the first direction polarized light is converted into the second direction polarized light which rotates in the opposite direction to the chiral optical structure and is reflected from the reflecting electrode.

14. The circularly polarized light emitting display device of claim 13, wherein the light whose direction of circular polarization is converted and which is reflected as the second direction polarized light rotates in the opposite direction to the chiral optical structure and rotates in the same direction as anti-reflective circularly polarized light for which the linear polarizer and a phase retardation layer are stacked, and the light is released as the light passes through the light emitting element layer, the selective reflection layer, and the circular polarization layer.

15. The circularly polarized light emitting display device of claim 14, wherein primary circularly polarized light generated from the light emitting element layer and secondary circularly polarized light reflected from the selective reflection layer and the reflecting electrode are released at different times and combined together, and the combined circularly polarized light has the same direction of polarization rotation as a polarization anti-reflection layer of a circular polarizer including a linear polarizer and the phase retardation layer, thereby improving the light emission efficiency of the light emitting display without optical loss caused by the polarizer.

16. The circularly polarized light emitting display device of claim 15, wherein the selective reflection layer includes a chiral liquid crystal layer so that refractive indices n1 and n2 appear repeatedly during rotation.

17. The circularly polarized light emitting display device of claim 16, wherein the chiral layer is produced by a process of giving the chiral structure left handed chirality and/or right handed chirality.

18. The circularly polarized light emitting display device of claim 17, wherein the chiral layer is configured in such a way that the force of rotation per unit length changes with changing temperature of the chiral structure, and the wavelength of reflected light becomes shorter or longer as the temperature of the chiral structure rises.

19. The circularly polarized light emitting display device of claim 18, wherein the circularly polarized light emitting display is composed of organic, inorganic, and organic-inorganic hybrid materials, quantum dots, a perovskite, a quantum nanowire, and an organic light emitting semiconductor, and has at least one polarizer.

20. The circularly polarized light emitting display device of claim 16, wherein the chiral layer is formed integrally with the light emitting element layer.
